(19) United States
(12) Patent Application Publication
(10) Pub. No.: US 2015/0216068 A1
(43) Pub. Date: Jul. 30, 2015

(54) SENSOR PACKAGE AND METHOD OF MANUFACTURING THE SAME

(71) Applicant: SAMSUNG ELECTRO-MECHANICS CO., LTD., Suwon-Si (KR)

(72) Inventors: Seoung Ho KIM, Suwon-Si (KR); Tae Sung Jeong, Suwon-si (KR); Min Seok Jang, Suwon-si (KR)

(73) Assignee: SAMSUNG ELECTRO-MECHANICS CO., LTD., Suwon-Si (KR)

(21) Appl. No.: 14/339,188

(22) Filed: Jul. 23, 2014

(30) Foreign Application Priority Data
Jan. 29, 2014 (KR) 10-2014-0011642

(51) Int. Cl. H05K 7/14; H05K 13/04

(52) U.S. Cl. CPC H05K 7/14; H05K 13/04

(57) ABSTRACT

Disclosed herein are a sensor package and a method of manufacturing the same. According to the embodiment of the present invention, a sensor package includes: a metal frame; a sensor chip formed on the metal frame and including a sensing part; a protective layer formed on the sensor chip and formed on remaining portions except for the sensing part; and a molding part formed to cover the metal frame and the sensor chip, wherein an upper surface of the protective layer and an upper surface of the molding part are disposed on the same surface.

### CROSS REFERENCE TO RELATED APPLICATION

This application claims the benefit of Korean Patent Application No. 10-2014-0011642, filed on Jan. 29, 2014, entitled “Sensor Package And Method Of Manufacturing The Same” which is hereby incorporated by reference in its entirety into this application.

### BACKGROUND OF THE INVENTION

1. Technical Field

Embodiments of the present invention relate to a sensor package and a method for manufacturing the same.

2. Description of the Related Art

At present, packaging of a device which is adopted in mobile devices, such as a smart phone and a tablet PC has a tendency toward miniaturization and high performance. That is, as the packaging is miniaturized, attempts to add more functions to the same space have been conducted.

In particular, the miniaturization of parts having additional functions, not a main part, has been strongly asked. Therefore, a competitive power of part manufacturing companies may be rely on how small they may manufacture the parts. Meanwhile, with the tendency of the miniaturization of the mobile device, the size reduction of the sensor package has been continuously asked.

### PRIOR ART DOCUMENT

### Patent Document

(Patent Document 1) Korean Patent Laid-Open Publication No. 2013-0023901

### SUMMARY OF THE INVENTION

Embodiments of the present invention have been made in an effort to provide a sensor package and a method of manufacturing the same capable of exposing a sensing part on a surface of a package by making upper positions of a protective layer and a package molding part, which are formed on a sensor chip, the same, thereby improving sensitivity.

Further, the embodiments have been made in an effort to provide a sensor package and a method of manufacturing the same capable of forming a molding part without using the mold tool at the time of machining a sensing part.

According to an embodiment of the present invention, there is provided a sensor package including: a metal frame; a sensor chip formed on the metal frame and including a sensing part; a protective layer formed on the sensor chip and formed to have an opening at a position corresponding to the sensing part; and a molding part formed to cover the metal frame and the sensor chip, wherein an upper surface of the protective layer and an upper surface of the molding part are disposed on the same surface.

The sensor package may further include: side metal frames formed to be spaced apart from the metal frame and formed at both sides of the metal frame.

The sensor package may further include: a wire electrically connecting the side metal frame to the sensor chip.

The sensor package may further include: an adhesive layer interposed between the metal frame and the sensor chip.

The protective layer may be made of polymer.

According to another embodiment of the present invention, there is provided a method of manufacturing a sensor package including: preparing a metal frame; preparing a sensor chip on which a protective layer is formed mounting the sensor chip on the metal frame; and forming a molding part to cover the metal frame and the sensor chip, wherein an upper surface of the molding part and an upper surface of the protective layer are formed to be disposed on the same surface.

The preparing of the metal frame may include forming side metal frames at both sides of the metal frame to be spaced apart from the metal frame.

The method of manufacturing a sensor package may further include: prior to the forming of the molding part, forming a wire electrically connecting the side metal frames to the sensor chip.

The method of manufacturing a sensor package may further include: prior to the mounting of the sensor chip, interposing an adhesive on the metal frame.

The protective layer may be made of polymer.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view of a sensor package according to a embodiment of the present invention; and

FIGS. 2 through 6 are flow charts sequentially illustrating a sensor package according to another embodiment of the present invention.

### DESCRIPTION OF THE PREFERRED EMBODIMENTS

The aspects, features and advantages of the present invention will be more clearly understood from the following detailed description of the embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, embodiments of the present invention will be described in detail with reference to the accompanying drawings.

Sensor Package

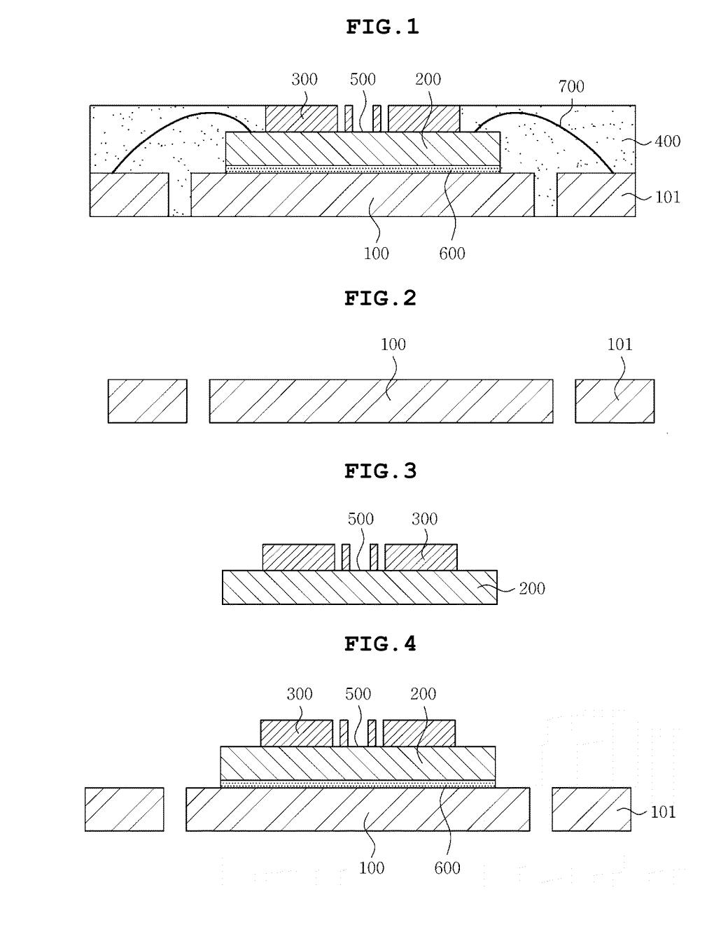

FIG. 1 is a cross-sectional view of a sensor package according to an embodiment of the present invention.

As illustrated in FIG. 1, a sensor package according to an embodiment of the present invention includes a metal frame 100, a sensor chip 200 which is formed on the metal frame and includes a sensing part 500, a protective layer 300 which is formed on the sensor chip 200 and is formed to have an opening at a position corresponding to the sensing part 500, and a molding part 600 which is formed to cover the metal frame 100 and the sensor chip 200, in which an upper surface of the protective layer 300 and an upper surface of the molding part 600 are disposed on the same surface.

By the above configuration, it is possible to miniaturize the sensor package. Referring to FIG. 1, the upper surface of the protective layer 300 and an exposed upper surface of the sensor chip 300 may be formed to have a step.

According to the embodiment of the present invention, the protective layer 300 may be formed on a part of the sensor chip 200 and a height thereof may be formed at 75 μm or less.

In this case, the protective layer 300 may be formed to have the opening through which the sensing part 500 is exposed. By the above configuration, sensitivity of the sensing part 500 may be improved.

In this case, the sensing part 500 may serve to sense a specific physical and chemical measurement amount to be measured from the outside.

Further, as illustrated, the protective layer 300 may be formed to protect the surface of the sensor chip 200 and may be formed, excluding a wire forming region to be described below.

Here, the protective layer 300 may be made of an insulating material, for example, polymer.

Further, various types of sensor chips 200 may be provided. The embodiment of the present invention may use a temperature sensor and a humidity sensing sensor, but is not limited thereto. For example, the sensor chip 200 may include other types of sensors which may be sensed by the sensing part 500 of the exposed sensor chip 200.

Here, an adhesive layer 600 may be interposed between the sensor chip 200 and the metal frame 100. As widely known, as the adhesive layer 600, an anisotropic conductive film (ACF), a non conductive film (NCF), and the like may be used, but the adhesive layer 600 are not limited thereto. The adhesive layer 600 may serve to bond the metal frame 100 to the sensor chip 200.

Further, the sensor package may include side metal frames 101 which are formed to be spaced apart from the metal frame 100 and are formed at both sides of the metal frame 100.

In this case, a wire 700 may be formed to electrically connect the side metal frames 101 to the sensor chip 200.

As the wire 700, aluminum (Al), gold (Au), copper (Cu), and the like may be used, but the wire 700 is not particularly limited thereto.

Further, the molding part 400 may be formed to cover the metal frame 100, the side metal frame 101, and the sensor chip 200.

Here, since a molding material forming the molding part 400 is formed to be filled in upper portions of the metal frame 100 and the side metal frame 101, an adhesion between the molding material and a frame may be increased. As the result, the occurrence of problems such as delamination is reduced and thus the long-term reliability of the metal frame 100 may be improved. Further, heat is shielded due to the molding and therefore a heat sink effect may be more improved.

In this case, as the molding part 400 may be made of a silicon gel, an epoxy molding compound (EMC), and the like, the embodiment of the present invention is not limited thereto.

Here, the upper surface of the molding part 400 may be formed to be disposed on the same surface as the upper surface of the protective layer 300.

Method of Manufacturing Sensor Package

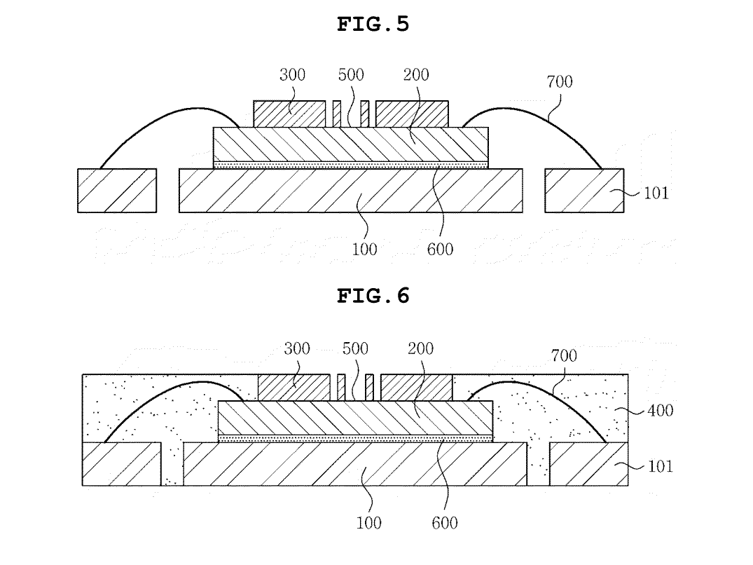

FIGS. 2 through 6 are flow charts sequentially illustrating a method of manufacturing a sensor package according to another embodiment of the present invention.

As illustrated in FIG. 2, the metal frame 100 is prepared.

Further, the side metal frames 101 may be formed to be spaced apart from both sides of the metal frame 100 at a predetermined interval.

Next, as illustrated in FIG. 3, the sensor chip 200 on which the protective layer 300 is formed is prepared.

Here, the sensor chip 200 includes the sensing part 500.

Further, the protective layer 300 may be formed at a part of the sensor chip 200 to have an opening at a position corresponding to the sensing part 500. By the above configuration, the sensitivity of the sensing part 500 may be improved.

In this case, the sensing part 500 may serve to sense a specific physical and chemical measurement amount to be measured from the outside.

Further, as illustrated, the protective layer 300 may be formed to protect the surface of the sensor chip 200 and may be formed, excluding the wire forming region to be described below.

Here, the protective layer 300 may be made of an insulating material, for example, polymer.

According to the embodiment of the present invention, the height of the protective layer 300 may be formed at 75 μm or less.

In this case, the protective layer 300 having the opening corresponding to the sensing part 500 is first formed on the sensor chip 200 to be able to suppress the occurrence of defect of the alignment of the sensing part 500 to expose the accurate position of the sensing part 500.

As illustrated in FIG. 4, the sensor chip 200 on which the protective layer 300 is formed may be mounted on the prepared metal frame 100.

Here, the adhesive layer 600 may be interposed between the sensor chip 200 and the metal frame 100. For example, as the material of the adhesive layer 600, the anisotropic conductive film (ACF), the non conductive film (NCF), and the like may be used and the material of the adhesive layer 600 is not limited thereto. The adhesive layer 600 may serve to bond the metal frame 100 to the sensor chip 200.

As illustrated in FIG. 5, the wire 700 may be formed to electrically connect the side metal frame 101 to the sensor chip 200.

As the wire 700, aluminum (Al), gold (Au), copper (Cu), and the like may be used, but the wire 700 is not particularly limited thereto.

As illustrated in FIG. 6, the molding part 400 may be formed to cover the metal frame 100, the side metal frame 101, and the sensor chip 200.

Here, the molding material forming the molding part 400 is formed to be filled in the upper portions of the metal frame 100 and the side metal frame 101, and therefore the adhesion between the molding material and the frame may be increased. As the result, the occurrence of the problems such as delamination is reduced, and thus the long term reliability of the metal frame 100 may be improved.

Further, heat is shielded due to the molding and therefore a heat sink effect may be more improved.

In this case, as the material of the molding part 400, a silicon gel, an epoxy molding compound (EMC), and the like, may be used, but the embodiment of the present invention is not limited thereto.

Here, the upper surface of the molding part 400 may be formed to be disposed on the same surface as the upper surface of the protective layer 300.

According to the sensor package according to the exemplary embodiment of the present invention, it is possible to implement the miniaturization and thinness of the package by making the upper positions of the protective layer and the package molding part, which are formed on the sensor chip, the same and expose the sensing part on the surface of the package, thereby improving the sensitivity.

Further, it is possible to make the alignment of the sensing part accurate by not using the mold tool at the time of machining the sensing part.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A sensor package, comprising:
a metal frame;
a sensor chip formed on the metal frame and including a sensing part;
a protective layer formed on the sensor chip and formed to have an opening at a position corresponding to the sensing part; and
a molding part formed to cover the metal frame and the sensor chip,
wherein an upper surface of the protective layer and an upper surface of the molding part are disposed on the same surface.

2. The sensor package as set forth in claim 1, further comprising:
side metal frames formed to be spaced apart from the metal frame and formed at both sides of the metal frame.

3. The sensor package as set forth in claim 2, further comprising:
a wire electrically connecting the side metal frame to the sensor chip.

4. The sensor package as set forth in claim 1, further comprising:
an adhesive layer interposed between the metal frame and the sensor chip.

5. The sensor package as set forth in claim 1, wherein: the protective layer is made of polymer.

6. A method of manufacturing a sensor package, comprising:
preparing a metal frame;
preparing a sensor chip on which a protective layer is formed;
mounting the sensor chip on the metal frame; and
forming a molding part to cover the metal frame and the sensor chip,
wherein an upper surface of the molding part and an upper surface of the protective layer are formed to be disposed on the same surface.

7. The method as set forth in claim 6, wherein the preparing of the metal frame includes forming side metal frames at both sides of the metal frame to be spaced apart from the metal frame.

8. The method as set forth in claim 7, further comprising:
prior to the forming of the molding part, forming a wire electrically connecting the side metal frames to the sensor chip.

9. The method as set forth in claim 6, further comprising:
prior to the mounting of the sensor chip, interposing an adhesive on the metal frame.

10. The method as set forth in claim 6, wherein the protective layer is made of polymer.
